(19) United States
(12) Patent Application Publication
(10) Pub. No.: US 2006/0280945 A1
(43) Pub. Date: Dec. 14, 2006

(54) Method of synthesising a crystalline material and material thus obtained

(76) Inventor: Didier Pribat, Sevres (FR)

Correspondence Address: FISH & RICHARDSON PC, P.O. BOX 1022, MINNEAPOLIS, MN, 55440-1022, US

(21) Appl. No.: 10/561,761

(22) PCT Filed: Jun. 25, 2004
(86) PCT No.: PCT/FR04/01634

§ 371 Date: Dec. 21, 2005

(30) Foreign Application Priority Data
Jun. 27, 2003 (FR) 03/07849

(51) Int. Cl. B32B 9/00; H01L 21/20; H01L 21/36

(52) U.S. Cl. 428/408; 438/478

(57) ABSTRACT

The invention provides a method of synthesizing a crystalline material in which seeds (6) are produced of a catalyst that is adapted to dissolve carbon on a substrate (2) of a first material; carbon nanotubes (6) are grown from the seeds (6); and a layer is produced of a second material comprising at least one monocrystalline region (12) orientated from a seed (6). The invention also provides the material obtained by said method. Application to the synthesis of polycrystalline silicon on a glass substrate.

The invention relates to a method of synthesizing a crystalline material, and to the material obtained thereby.

More particularly, the invention concerns a method of synthesizing a crystalline material, comprising the steps of:

a) producing seeds of a catalyst adapted to dissolve carbon on a substrate constituted by a first material;

b) growing carbon nanotubes from the seeds; and

c) producing a layer of a second material comprising at least one monocrystalline region orientated from a seed.

The method of the invention can produce a layer of silicon which is at least partially crystalline, such as polycrystalline silicon, on an amorphous substrate such as glass. In this case in particular, the product obtained by the method of the invention is particularly advantageous for electronics applications such as the fabrication of flat screens.

To optimize the orientation of monocrystalline domains with respect to each other, during step b), the seeds are orientated in a magnetic field.

The method of the invention may also comprise one or more of the following dispositions:

the first material is an amorphous material;

the catalyst comprises a transition metal;

the second material is silicon;

step c) comprises the following sub-steps:
c1), during which the second material is deposited in an amorphous form on the substrate and seeds located at the tops of carbon nanotubes; then
c2), during which the second material is crystallized in the solid phase;

step a) comprises the following sub-steps:

a1), during which studs of catalyst are produced on the substrate; then
a2), during which the substrate and the studs are annealed to form seeds;

step a) comprises the following sub-steps:

a′1), during which a thin film constituted by catalyst is deposited on the substrate; then
a′2), during which the substrate and the thin film are annealed to form seeds;

step a) comprises the following sub-steps:
a″1), during which metal ions are implanted into a thin layer;
a″2), during which the thin layer into which ions have been implanted is annealed to form metallic precipitates from the implanted ions;
a″3), during which selective attack of the thin layer is carried out to cause metallic precipitates, which will form seeds, to appear on the surface; and

a magnetic field is applied during steps a2), a′2) or a″2) to orientate the seeds;

step a) comprises the following sub-steps:
a″′1), of depositing a layer of masking resin on the thin layer, of producing patterns in the resin, and of etching the thin layer at the patterns to form pits;
a″′2), of depositing the second material;
a″′3), of dissolving resin; and
a″′4), of annealing the thin layer and second material in the pits to form seeds.

In another aspect, the invention provides a material comprising:

a substrate constituted by a first material extending essentially in a plane;

carbon nanotubes extending longitudinally essentially perpendicular to the plane of the substrate between a free end and an end which is fixed to the substrate;

seeds of a catalyst substantially located near the free end of carbon nanotubes; and

at least one domain of a second crystalline material orientated from at least one seed.

The above characteristics and others become more apparent from the following description of two particular implementations of the invention, given by way of non-limiting example.

The description is made with reference to the accompanying drawings, in which:

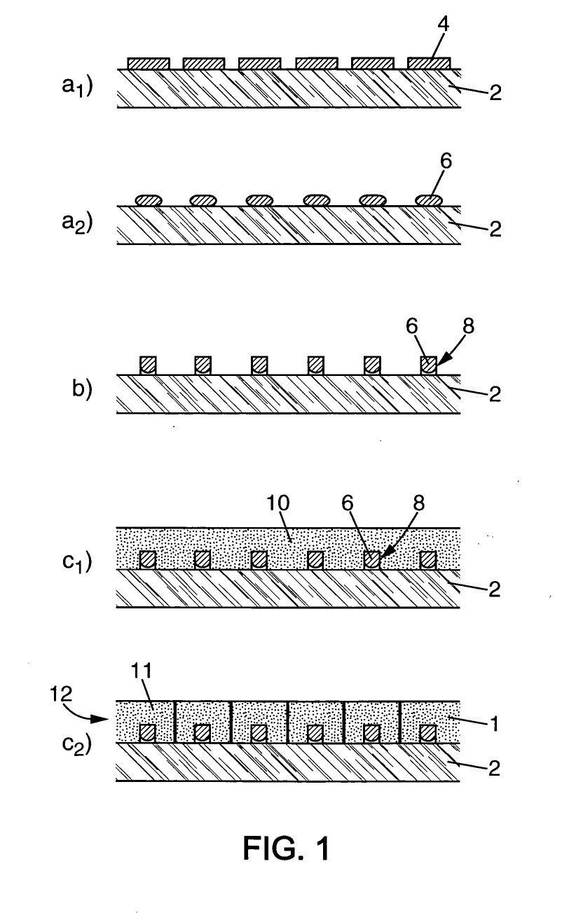

FIG. 1 is a diagram showing a first implementation of the method of the invention;

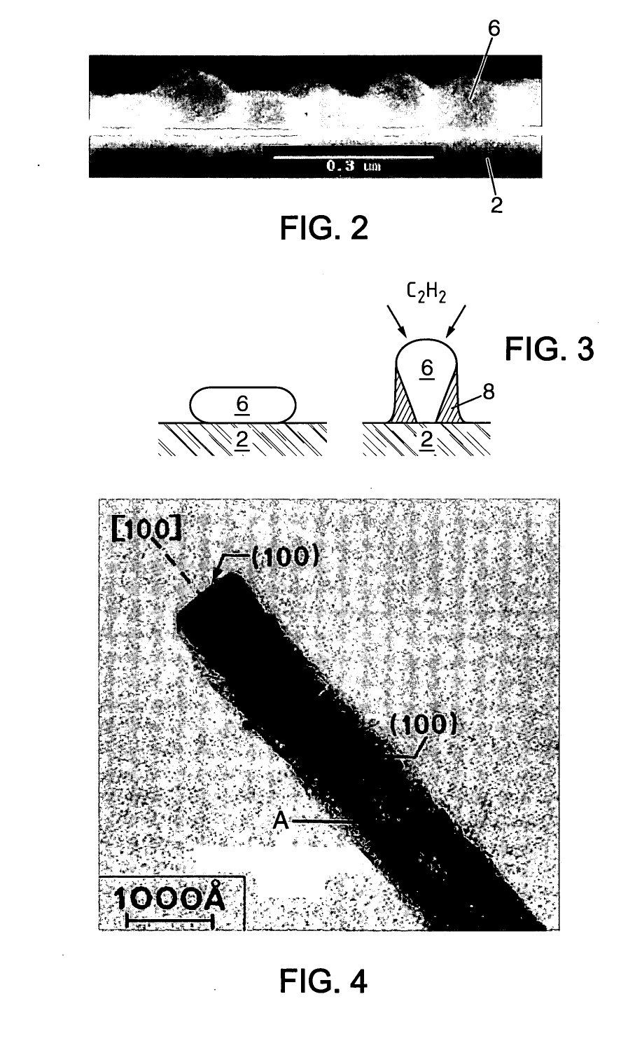

FIG. 2 is a photographic scanning electron microscope image of a substrate on which seeds have been formed in accordance with the first steps of the method of FIG. 1;

FIG. 3 is a diagrammatic sectional view showing the start of growth of carbon nanotubes from seeds such as those shown in FIG. 2;

FIG. 4 is a photographic transmission electron microscope image of the free end of a carbon nanotube and of the seed which aided its growth;

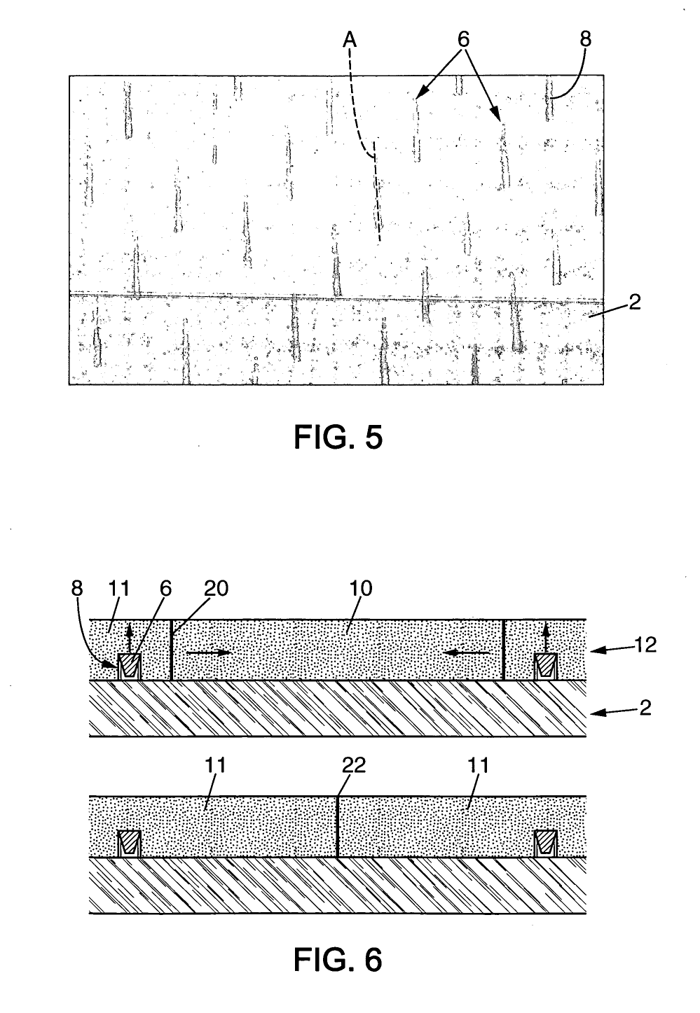

FIG. 5 is a photographic scanning electron microscope image of a set of carbon nanotubes grown in accordance with the first steps of the method of FIG. 1;

FIG. 6 is a diagrammatic section through a substrate showing crystallization of a thin layer of amorphous silicon in accordance with the method illustrated by FIG. 1;

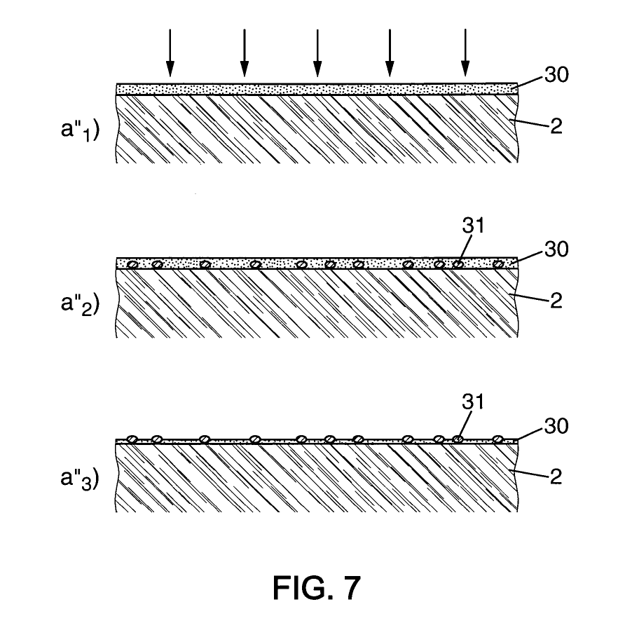

FIG. 7 is a diagram showing some steps in a second implementation of the method of the invention; and

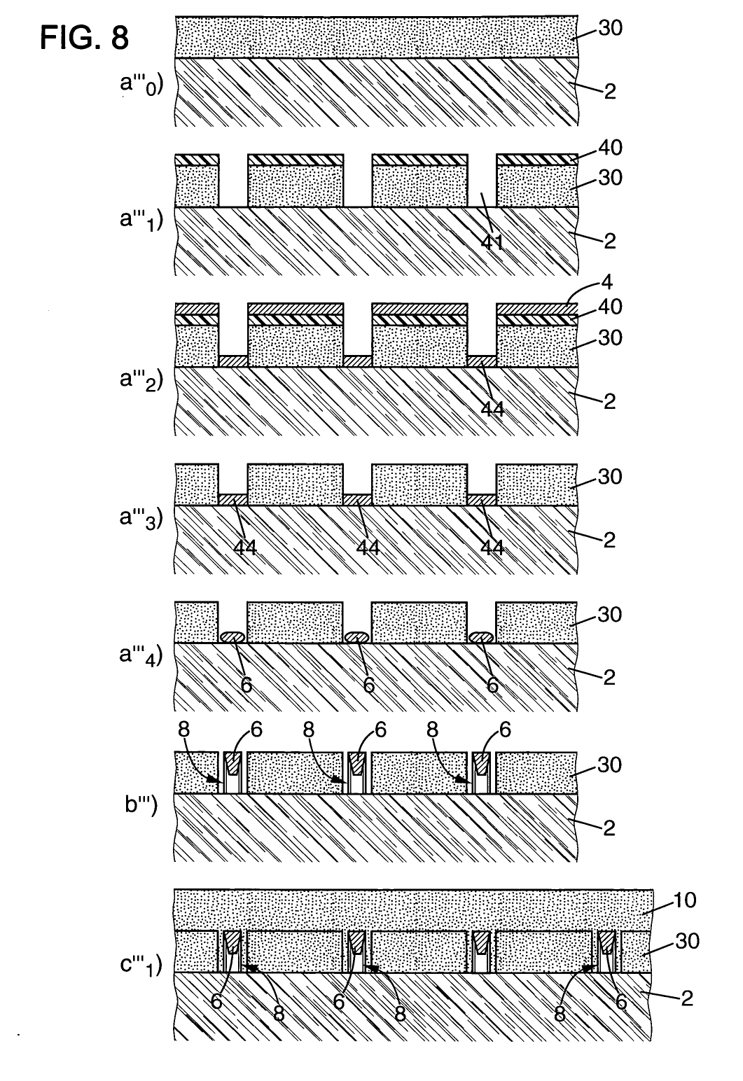

FIG. 8 is a diagram showing some steps in a third implementation of the method of the invention.

A first, non-limiting implementation of the method of the invention is described below with reference to FIGS. 1 to 6.

In this example, the method of the invention is applied to the production, on a substrate 2 of a first material, in this case glass, of a layer of a second material, in this case polycrystalline silicon (see FIG. 1 c2)).

In this example, the method comprises:

a step a1), during which studs 4 are produced on a substrate 2;

a step a2), during which the substrate 2 and the studs 4 are annealed to form seeds 6;

a step b) of growing carbon nanotubes 8 from the seeds 6;

a step c1), during which a layer of amorphous silicon 10 is deposited on the substrate 2, the seeds 6, and the carbon nanotubes 8; and

a step c2), during which the substrate 2, on which the amorphous silicon layer 10 has been deposited, is annealed to crystallize the silicon in the solid phase and obtain grains 11 of orientated silicon.

The studs 4 are constituted by a catalyst, in this case a metal, typically a transition metal, which catalyzes the growth of carbon nanotubes 8. It may be iron, cobalt, nickel, platinum, etc.

To form the studs 4, a thin layer, for example of iron, is deposited on the substrate 2 during step a1) and is then etched by conventional lithographic methods to form an array of studs 4. Said studs are typically spaced 2 micrometers (μm) to 3 μm apart.

During step a2), the thin layer of iron is annealed at 650° C.-750° C. in a reducing atmosphere.

In a variation, a thin layer, 10 nanometers (nm) thick, of catalyst is deposited on the substrate 2, and the whole is annealed.

FIG. 2 shows this variation, in which seeds 6 have been formed from a thin layer of nickel annealed at 700° C., thereby simplifying the manner in which the seeds 6 are obtained. In fact, it is not necessary to provide a regular, well ordered array. It is sufficient that on average, the seeds 6 are 3 μm to 6 μm apart (Y. Kunii, M. Tabe and K. Kajiyama, J. Appl. Phys., vol 54, p 2847 (1983)), to prevent homogeneous nucleation, in the amorphous silicon, between two seeds 6 during the crystallization step c2). In fact, homogeneous nucleation occurs in a random manner and the grains 11 thus generated would interrupt the organization of the silicon layer after crystallization.

During step b), carbon nanotubes 8 are grown from the seeds 6 by purely thermal chemical vapor deposition (CVD) at 850° C.-1000° C. or by plasma enhanced chemical vapor deposition (PECVD), at 600° C.-700° C. For that growth method, reference should be made, for example, to the article by M. Meyyappan et al, Plasma Sources Sci Technol, No 12, page 205 (2003).

As shown in FIG. 3, during said growth step, the carbon-containing species in the gas, in this case C₂H₂, are decomposed onto the seeds 6. The released carbon is dissolved by the seed 6 and precipitates on its flanks, which are generally cooler, giving rise to a nanotube 8. The shape of the seed 6 changes and moves at the free end of the nanotube 8, in the case when it interacts little with the substrate 2, i.e. when γa+γ*≧γb, in which γa, γb and γ* are the surface energies respectively of the catalyst, of the substrate 2, and of the catalyst/substrate 2 interface.

In this case, after growth, the orientation of the seed 2 with respect to the axis of the carbon nanotube 8 is not random (see M. Audier et al, J. Cryst. Growth No 55, page 549 (1981)).

In particular, as shown in FIG. 4 for seeds 6 of iron, it can be seen that the [100] axis of the seed 6 is parallel to the axis A of the carbon nanotube 8. The orientation may be different for other transition metals, but in all cases there is a precise correlation between the orientation of seed 6 and the axis of the carbon nanotube 8 after growth. The growth of the carbon nanotubes 8 transforms a seed 6 with a random orientation into a seed 6 with a precise orientation with respect to the axis of the carbon nanotube 8.

As shown in FIG. 5, if the carbon nanotubes 8 obtained by PECVD are all parallel and vertical, and if the seeds 6 have their [100] axis parallel to the axis A of carbon nanotubes 8, all of the seeds 6, after growth of the carbon nanotubes 8, have the same zone axis. The growth of the carbon nanotubes 8 in accordance with the method of the invention thus transforms a layer of catalyst with a completely random orientation into an array of seeds 6 at the tops of carbon nanotubes 8 with the same zone axis.

In order to perfect the orientation of the metallic seeds in the plane of substrate 2, a magnetic field which is judiciously orientated in the plane of substrate 2 may be applied during step a2) of forming the seeds 6, or during step b) of growing the carbon nanotubes 8 from the seeds 6.

During step c1), a thin layer of amorphous silicon 10 is deposited on the array of carbon nanotubes 8 at the tops of which the seeds 6 are orientated. This step c1) is carried out under conditions which are known to the skilled person, by PECVD or LPCVD (low pressure chemical vapor deposition), by decomposition of SiH₄ or Si₂H₆, at a temperature in the range 200° C. to 600° C.

During step c2), the layer of amorphous silicon 10 is crystallized in the solid phase in a controlled atmosphere furnace at a temperature which is typically in the range 450° C. to 550° C. A layer of polycrystalline silicon is thus obtained which is highly textured and has a surface orientation corresponding to the orientation of the seeds 6 at the tops of the carbon nanotubes 8. Solid phase silicon epitaxy takes place on the seeds 6. Since these seeds 6 have the same orientation, a final thin layer of highly textured polycrystalline 12 or even monocrystalline silicon is obtained on an amorphous substrate 2.

Growth and solid phase epitaxy of silicon on the seeds 6 are shown in FIG. 6. In a first stage of the growth, the crystallization front propagates from the tops of the seeds 6 into the thickness of the layer 10. Then, when the whole thickness of the layer 10 has crystallized, the crystallization front 20 moves parallel to the plane of the layer 10. The epitaxially grown silicon on the seeds 6, which is thus orientated thereon, crystallizes from each of seeds 6. The crystallization front 20 moves laterally to obtain a low disorientation grain boundary 22.

A second example, also non-limiting, of the method of the invention is described below with reference to FIG. 7. In this example, the method of the invention differs from that discussed above essentially in the steps of forming the seeds 6.

As shown in FIG. 7, a thin layer 30 of a dielectric material which is known to the skilled person is produced on an amorphous substrate 2. The dielectric material may, for example, be silica (SiO₂) or silicon nitride (Si₃N₄).

During a step a″1), metal ions are implanted in the thin layer 30. The metal ions correspond to the catalyst selected to form seeds 6.

During a step a″2), an anneal is carried out at about 600° C. of the substrate 2 and of the thin layer 30 that has undergone ionic implantation. During said anneal, the metal atoms precipitate out. The spacing and size of the precipitates 31 may be adjusted as a function of the implantation dose during step a″1). Typically, doses of the order of 10¹⁷ to 10¹⁸ ions per cm² are used.

During a step a″3), chemical attack of the thin layer 30 of dielectric is carried out to “expose” the metallic precipitates 31. The emergent portions of the metallic precipitates 31 constitute the seeds 6 from which growth of a carbon nanotube 8 and then deposition of amorphous silicon then its crystallization can be carried out following steps b), c1) and c2) of the first example of the method of the invention as described above.

A third example, again non-limiting, of implementing the method of the invention is described below with reference to FIG. 8. In this example, the implementation of the invention differs from those described above essentially in the steps of forming the seeds 6.

As shown in FIG. 8, in a step a″′0), a thin layer 30 of a dielectric material which is known to the skilled person is produced on an amorphous substrate 2. The dielectric material may, for example, be silica (SiO₂) or silicon nitride (Si₃N₄).

During a step a″′1)
a layer of masking resin 40 is deposited on the thin layer 30;

patterns are produced in the resin 40, for example by photolithography, such that the resin 40 masks the thin layer 30 except in certain zones where the thin layer 30 is exposed; and

the thin layer 30 is etched down to the substrate 2 at the exposed zones to form pits 41.

During a step a″′2), a metal catalyst 44 selected to form the seeds 6 is deposited.

During a step a″′3), the resin 40 is dissolved. The catalyst 44 present on the resin is thus also eliminated during said operation.

During a step a″′4), an anneal is carried out at about 600° C. of the substrate 2, the thin layer 30, and the catalyst 44 present at the bottoms of the pits 41. During said anneal, the catalyst forms seeds 6 in the form of nanoparticles.

A step b″′ is then carried out of growing carbon nanotubes 8 from the seeds 6 in a manner analogous to step b) described above, in order to orientate the seeds 6.

Finally, a step c″′1) is carried out of depositing a layer of amorphous silicon 10, then a step c″′2) (not shown) is carried out of crystallizing the layer of amorphous silicon 10, respectively analogous to steps c1) and c2) described above.

1. A method of synthesizing a crystalline material, comprising the steps of:
a) producing seeds (6) of a catalyst adapted to dissolve carbon on a substrate constituted by a first material;
b) growing carbon nanotubes from the seeds; and
c) producing a layer of a second material comprising at least one monocrystalline region orientated from a seed.

2. A method according to claim 1 in which, during step b), the seeds are orientated in a magnetic field.

3. A method according to claim 1, in which the first material is an amorphous material.

4. A method according to claim 1, in which the catalyst comprises a transition metal.

5. A method according to claim 1, in which the second material is silicon.

6. A method according to claim 1, in which step c) comprises the following sub-steps:
c1), during which the second material is deposited in an amorphous form on the substrate and seeds located at the tops of carbon nanotubes; then
c2), during which the second material is crystallized in the solid phase.

7. A method according to claim 1, in which step a) comprises the following sub-steps:
a1), during which studs of catalyst are produced on the substrate; then
a2), during which the substrate and the studs are annealed to form seeds.

8. A method according to claim 1, in which step a) comprises the following sub-steps:
a′1), during which a thin film constituted by catalyst is deposited on the substrate; then
a′2), during which the substrate and the thin film are annealed to form seeds.

9. A method according to claim 1, in which step a) comprises the following sub-steps:
a″1), during which metal ions are implanted into a thin layer;
a″2), during which the thin layer into which ions have been implanted is annealed to form metallic precipitates from the implanted ions;
a″3), during which selective attack of the thin layer is carried out to cause metallic precipitates, which will form seeds, to appear on the surface.

10. A method according to claim 7 in which, during steps a2), a magnetic field is applied to orientate the seeds.

11. A method according to claim 1, in which step a) comprises the following sub-steps:
a″′1), of depositing a layer of masking resin on the thin layer, of producing motifs in the resin, and of etching the thin layer at the motifs to form pits;
a″′2), of depositing the catalyst;
a″′3), of dissolving resin; and
a″′4), of annealing the thin layer and catalyst in the pits to form seeds.

12. A material comprising:
a substrate constituted by a first material extending essentially in a plane;
carbon nanotubes extending longitudinally essentially perpendicular to the plane of the substrate between a free end and an end which is fixed to the substrate;
seeds of a catalyst substantially located near the free end of carbon nanotubes; and
at least one domain of a second crystalline material orientated from at least one seed.

13. A method according to claim 8 in which, during step a′2), a magnetic field is applied to orientate the seeds.

14. A method according to claim 9 in which, during step a″2), a magnetic field is applied to orientate the seeds.
